(19) United States
(12) Patent Application Publication
(10) Pub. No.: US 2025/0364803 A1
(43) Pub. Date: Nov. 27, 2025

(54) APPARATUS AND METHOD FOR LIMITING A FAULT CURRENT IN A DC VOLTAGE NETWORK

(71) Applicant: Siemens Energy Global GmbH & Co. KG, München (DE)

(72) Inventors: Sebastian Semmler, Nürnberg (DE); Rodrigo Alonso Alvarez Valenzuela, Nürnberg (DE)

(21) Appl. No.: 19/217,043

(22) Filed: May 23, 2025

(30) Foreign Application Priority Data
May 23, 2024 (EP) 24177574.1

(51) Int. Cl. H02H 9/02

(52) U.S. Cl. CPC H02H 9/02

(57) ABSTRACT

An apparatus for limiting a fault current in a DC voltage connection. The apparatus includes a series connection of current-limiting modules, wherein each current-limiting module has a plurality of power semiconductor switches and a surge arrester connected in parallel with the power semiconductors. A control apparatus controls the power semiconductor switches, and is configured to actuate the power semiconductor switches by use of different gate-emitter voltages.

### CROSS-REFERENCE TO RELATED APPLICATION

This application claims the priority, under 35 U.S.C. § 119, of European Patent Application EP 24177574.1, filed May 23, 2024; the prior application is herewith incorporated by reference in its entirety.

### FIELD AND BACKGROUND OF THE INVENTION

The invention relates to an apparatus for limiting a fault current in a DC voltage connection containing a series connection of current-limiting modules, wherein each current-limiting module contains a plurality of power semiconductor switches and a surge arrester connected in parallel with the power semiconductors.

Apparatuses for limiting or suppressing fault currents (often referred to as DC circuit breakers or DC fault separation devices) are of importance for the operation of DC-voltage-based distribution and transmission networks (point-to-point, multi-terminal and meshed networks). In contrast to AC voltage/current, there are no natural current zero crossings in DC voltage networks, and therefore specific solution approaches are required for this application. For DC circuit breakers/DC fault separation devices, it is of particular importance that they have low on-state power losses. In order to suppress fault currents, power electronic apparatuses may be used, for which, in addition to the aforementioned minimization of on-state power losses, the avoidance of deratings represents a technical challenge on account of the parallel and series connection of semiconductors.

An apparatus mentioned at the outset is known from published, non-prosecuted German patent application DE 10 2015 211 339 A1. The known apparatus contains a power electronic DC circuit breaker containing a series connection of a plurality of semiconductor switching elements, which each have a power electronic switch and a surge arrester, and a freewheeling path electrically connected in parallel with this series connection of switches. The known solution differs from DC switches, which have mechanical switches in the operating current path (the path that carries the operating current during normal operation), by virtue of the power semiconductor switches being arranged in the operating current path in the case of the known DC circuit breaker.

### SUMMARY OF THE INVENTION

The object of the present invention is to provide an apparatus mentioned at the outset that exhibits as few losses as possible and is as reliable as possible during operation.

The object is achieved by an apparatus according to the features of independent apparatus patent claim.

With the foregoing and other objects in view there is provided, in accordance with the invention, an apparatus for limiting a fault current in a DC voltage connection. The apparatus contains a series connection of current-limiting modules. Each of the current-limiting modules has a plurality of power semiconductor switches and a surge arrester connected in parallel with the power semiconductors switches. A controller is provided for controlling the power semiconductor switches. The controller is configured to actuate the power semiconductor switches by use of different gate-emitter voltages.

According to the invention, the apparatus contains a control apparatus for controlling the power semiconductor switches, which is configured to actuate the power semiconductor switches by means of different gate-emitter voltages. The control apparatus is accordingly configured to switch on or disable the power semiconductor switches by means of control signals (it is connected to the respective gate of the relevant power semiconductor switch for this purpose). The power semiconductor switches are power semiconductor switches that are preferably able to be switched off, such as IGBTs, IGCTs, MOSFETs, JFETs, and SIC-based or GaN-based power semiconductor switches, for example.

The invention makes use of the knowledge that the collector-emitter voltage UCE (and therefore also the on-state power losses) at a power semiconductor generally depends on the applied gate-emitter voltage UGE (at least for currents of up to approximately 2.5 kA). In particular, the voltage UCE generally decreases when the voltage UGE is raised. Operation of a semiconductor switch with an increased UGE is described, for example, in international patent disclosure WO 2012/107010 A1, corresponding to U.S. Pat. No. 9,093,836.

However, according to the present invention, not all power semiconductor switches are operated by means of one (and the same) increased voltage UGE. Instead, the power semiconductor switches are operated in a controlled manner by means of different gate-emitter voltages in order to increase the reliability of the apparatus.

Suitably, the gate-emitter voltage is between 18 V and 35 V for the positive voltage, or is 0 V to −15 V for the negative voltage. When the power semiconductor switch is disabled, the collector-emitter voltage UCE may be from 1 kV to 10 kV. By way of example, the forward voltage may be up to 10 V. In addition to the activation or deactivation of all the current-limiting modules, the control apparatus is preferably configured to actuate only some of the modules, for example to gently suppress currents or to limit them to a maximum value.

Expediently, the control apparatus is configured to actuate at least a first power semiconductor switch of a current-limiting module by means of a first gate-emitter voltage that corresponds to a nominal gate-emitter voltage, and to actuate at least a second power semiconductor switch of the same current-limiting module by means of a second gate-emitter voltage, the magnitude of which is higher than the nominal gate-emitter voltage. The control apparatus is in particular configured to actuate two power semiconductor switches of one and the same current-limiting module by means of different gate-emitter voltages. By way of example, a first power semiconductor switch may be actuated by means of a first gate-emitter voltage, which may be a nominal gate-emitter voltage. By way of example, the nominal gate-emitter voltage is specified by the manufacturer of the relevant power semiconductor. A second power semiconductor switch may be actuated by means of a gate-emitter voltage that is increased in relation to this.

Preferably, at least one current-limiting module contains at least two power semiconductor switches, which are arranged in a series connection. In particular, each current-limiting module may respectively comprise two power semiconductor switches connected in series. The power semiconductor switches connected in series are actuated by means of different gate-emitter voltages (a first power semiconductor switch of the series connection is actuated by means of a first gate-emitter voltage, a second power semiconductor switch of the series connection is actuated by means of a second gate-emitter voltage that is different to, for example higher than, the first gate-emitter voltage), in such a way that, during operation of the apparatus, the same voltage is dropped across each of the power semiconductor switches, as a result of which the load on the power semiconductors is balanced and the reliability of the apparatus is therefore increased.

This makes it possible to influence the voltage division by way of the gate-emitter voltage (for example on the basis of active overvoltage limitation by manipulating the turn-off voltage in the range of −15 V up to slightly positive voltages). This advantageously allows the series connection to be provided without derating in the voltage utilization of the semiconductors.

Suitably, at least one current-limiting module contains at least two power semiconductor switches, which are arranged in antiseries with one another. In particular, each current-limiting module may respectively comprise (at least) two power semiconductor switches connected in antiseries. An antiseries connection in this case should be understood to mean that the power semiconductor switches are arranged in series with one another, but with mutually opposing forward directions or reverse directions. This achieves a bidirectional switch-off capability of the apparatus.

According to one embodiment of the invention, at least one current-limiting module contains at least two power semiconductor switches, which are arranged in a parallel connection with one another. In particular, each current-limiting module may respectively comprise (at least) two power semiconductor switches connected in parallel. In principle, the parallel connection increases the current-carrying capability of the apparatus. It is advantageous to be able to compensate for asymmetries in the mechanical structure (parasitic resistances and inductances) by way of (for example, minor) adjustment of the gate-emitter voltage. In particular, the power semiconductor switches connected in parallel are actuated by means of different gate-emitter voltages (a first power semiconductor switch of the parallel connection is actuated by means of a first gate-emitter voltage, a second power semiconductor switch of the parallel connection is actuated by means of a second gate-emitter voltage that is different to the first gate-emitter voltage), in such a way that the same current flows through the power semiconductors connected in parallel, as a result of which the load on the power semiconductors is balanced and the reliability of the apparatus is therefore further increased.

According to a particularly preferred embodiment of the invention, at least one current-limiting module contains at least four power semiconductor switches, which are arranged in a parallel connection of in each case two power semiconductor switches arranged in antiseries with one another. According to this embodiment, the advantages of the antiseries and parallel connection of power semiconductor switches described above may be combined. Of course, the current-limiting module may comprise more than two power semiconductors arranged in parallel. A series connection of a plurality of power semiconductor switches is also conceivable. It may be advantageous for some or even all of the current-limiting modules to have such a design with series, antiseries and/or parallel power semiconductor switches. Multiple parallel connections are expediently possible in order to enable scalability in terms of nominal current and maximum permissible fault current.

Preferably, at least one current-limiting module, particularly preferably all of the current-limiting modules, comprises/comprise a bypass switch for bypassing the current-limiting module in the event of a fault. The bypass switch is preferably a fast (typically mechanical) closing element that is connected in parallel with the power semiconductor switches of the current-limiting module. Individual faulty current-limiting modules may be bypassed by means of the bypass switch or switches. This makes it possible to ensure reliable operation of the entire apparatus.

Suitably, at least one current-limiting module comprises a parallel resistor that is connected in parallel with the surge arrester. It may be advantageous for all the current-limiting modules to each comprise such a parallel resistor. The parallel resistor internal to the current-limiting module provides balanced voltage division within the entire apparatus when said apparatus is deactivated (=switched off).

The apparatus may further comprise a power supply device for supplying energy to the current-limiting modules, which is galvanically isolated from the current-limiting modules. By way of example, the power supply device may comprise a central auxiliary energy supply (device power supply) that supplies energy to the current-limiting modules in a galvanically isolated manner (for example, by way of laser transmission).

The power semiconductor switches are suitably able to be cooled by means of an active cooling system. This may be implemented by means of a water cooling system, for example.

The apparatus preferably comprises a series connection of more than two current-limiting modules. The power semiconductor switches may be either with or without an integrated (antiparallel) diode (then as a separate element). The power semiconductor switches may further have either normally-off or normally-on characteristics (also referred to as the depletion type or enhancement type of the semiconductor). Adjustment to the desired system behavior (safe-state-off) is effected via a control unit (module control unit) internal to the current-limiting module. The module control unit is generally configured to actuate the power semiconductors, monitor the module state and communicate with the higher-level closed-loop control system or open-loop control system. It is supplied with auxiliary energy by a module supply unit (module power supply). The surge arrester into which the DC current commutates as soon as the power semiconductor switches are opened (disabled) is connected in parallel with the antiseries interconnection of the power semiconductors in the current-limiting module. The DC current flowing through the current-limiting module is thus suppressed at high impedance (energy consumption) and reduced to a low residual current (e.g. <10 A).

Within the apparatus, a variable number n of current-limiting modules are connected in series (n>2) in order to allow adjustment to various nominal voltages and redundancy. The apparatus furthermore contains the control apparatus (device control unit), which actuates the current-limiting modules (including the gate drivers with a gate-emitter voltage that is increased in a controllable manner) and monitors the state thereof. In addition to the activation or deactivation of all the current-limiting modules, the device control unit is capable of actuating only some of the current-limiting modules, for example to gently suppress currents or to limit them to a maximum value.

The invention is advantageously able to be used in a DC voltage network comprising a plurality of power converters that are connected to one another by means of DC voltage connections, wherein it is possible to limit a fault current in one of the DC voltage connections by means of at least one apparatus according to the invention. In the event of a fault in the DC voltage network, the apparatus or apparatuses may be used to isolate the fault location, to resolve the fault, and to enable the part of the DC voltage network not affected by the fault to continue to operate.

The invention further relates to a method for limiting a fault current in a DC voltage connection by means of an apparatus containing a series connection of current-limiting modules, wherein each current-limiting module contains a plurality of power semiconductor switches and a surge arrester connected in parallel with the power semiconductors, and a control apparatus for controlling the power semiconductor switches. In the method according to the invention, the power semiconductor switches are actuated by means of different gate-emitter voltages.

The advantages of the method according to the invention correspond in particular to those that have already been described in connection with the apparatus according to the invention.

Other features which are considered as characteristic for the invention are set forth in the appended claims.

Although the invention is illustrated and described herein as embodied in an apparatus and a method for limiting a fault current in a DC voltage network, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic illustration of an exemplary embodiment of a DC voltage network according to the invention;

FIG. 2 is a schematic illustration of an exemplary embodiment of an apparatus for limiting a fault current according to the invention; and

FIG. 3 is a schematic illustration of an example of a current-limiting module.

### DETAILED DESCRIPTION OF THE INVENTION

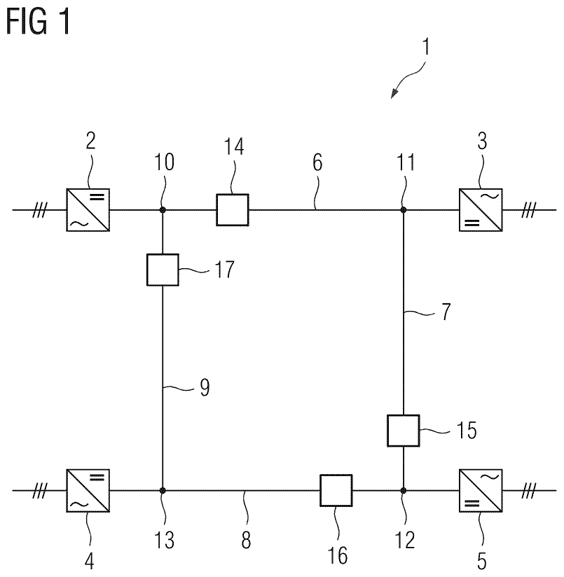

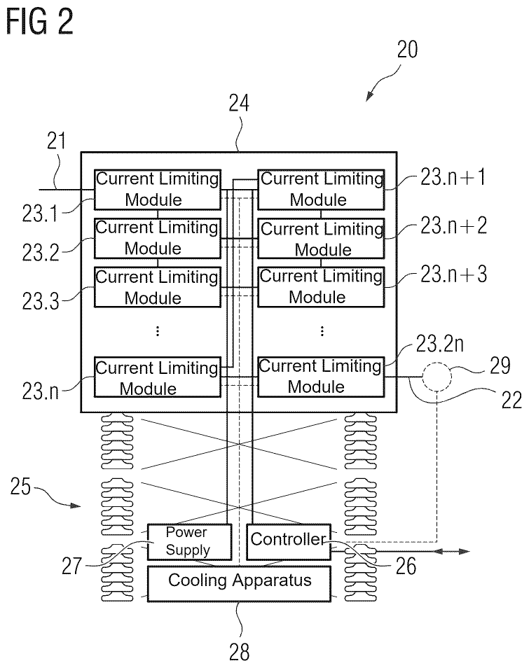

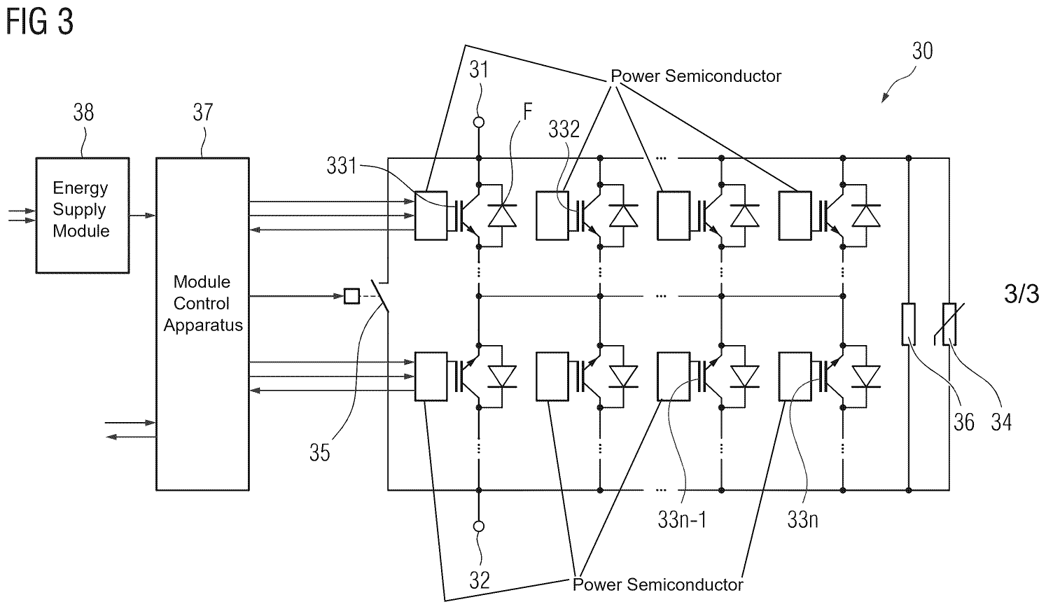

Referring now to the figures of the drawings in detail and first, particularly to FIG. 1 thereof, there is shown a DC voltage network 1. The DC voltage network 1 has four power converters 2-5 that are each arranged between an AC voltage network and the DC voltage network 1. The power converters 2-5 are connected to one another by means of DC voltage connections 6-9. The DC voltage connections 6-9 may be monopolar or else, for example, bipolar connections. The DC voltage connections 6-9 are coupled to one another at DC voltage nodes 10-13. A first, a second, a third and a fourth apparatus 14-17 are arranged in spatial proximity to two DC voltage nodes 10 and 12, by means of which apparatuses a fault current in the associated DC voltage connection 6-9 is able to be limited. The following FIGS. 2 and 3 deal with the design of the apparatuses in more detail.

FIG. 2 illustrates an apparatus 20 for limiting a fault current in a DC voltage connection (also referred to as a fault separation device), for example, one of the DC voltage connections 6-9 of FIG. 1. The apparatus 20 contains a first terminal 21, a second terminal 22 and a series connection of current-limiting modules 23.1 to 23.2n. FIG. 3 subsequently deals with the design of the current-limiting modules 23.1-23.2n in more detail.

The current-limiting modules 23.1-23.2n are arranged in a receiving apparatus 24 that is isolated from the ground potential by means of isolators 25. The apparatus 20 further contains a control apparatus 26 for controlling the current-limiting modules 23.1-23.2n or the power semiconductor switches thereof, a power supply device 27 for supplying energy to the current-limiting modules 23.1-23.2n, a cooling apparatus 28 for cooling the current-limiting modules 23.1-23.2n or the power semiconductors thereof and a measuring device 29 for recording measured variables such as current and/or voltage at the apparatus 20.

FIG. 3 illustrates a current-limiting module 30, which may be, for example, one of the current-limiting modules 23.1-23.2n. The current-limiting module 30 has a first module terminal 31 and a second module terminal 32. The current-limiting module 20 contains power semiconductor switches 331-33n that are connected in antiseries and in parallel with one another. Each power semiconductor switch 331-33n has a freewheeling diode F connected in antiparallel therewith.

A surge arrester 34 into which the DC current (fault current) commutates as soon as the power semiconductor switches are opened (disabled) is connected in parallel with the power semiconductors 331-33n in the current-limiting module 30. The DC current flowing through the current-limiting module is 30 thus suppressed at high impedance (energy consumption) and reduced to a low residual current (e.g. <10 A).

The number of current-limiting modules in an apparatus according to the invention is selected such that the entire apparatus is able to remain in operation and perform its function (redundancy) even if some current-limiting modules fail. Accordingly, a fast, mechanical closing element or bypass switch 35 is connected in parallel with the power semiconductor switches 331-33n of the current-limiting module 30 in order to be able to bypass individual faulty current-limiting modules and thus ensure reliable operation of the entire apparatus.

A parallel resistor 36 is used to achieve a uniform (balanced) voltage division within the current-limiting module 30 when the power semiconductor switches 331-33n are disabled.

The current-limiting module 30 further contains a module control apparatus 37 that is connected to the gates of the power semiconductor switches 331-33n and to a central part of the control apparatus (no. 26 in FIG. 2). The central part of the control apparatus, together with all of the module control apparatuses, forms the control apparatus for actuating the power semiconductor switches. The module control apparatus 37 in particular contains the corresponding gate drivers with a gate-emitter voltage that is increased in a controllable manner. The module control apparatus 37 is designed to actuate the power semiconductors, to monitor the module state and to communicate with higher-level control apparatuses.

A module energy supply module 38 is provided for supplying energy to the module control apparatus and, for this purpose, is connected to a central power supply device in a galvanically isolated manner (for example by means of an optical fiber).

During operation, the first power semiconductor switch 331 is actuated by means of a nominal gate-emitter voltage (for example according to the data sheet or the corresponding specification of the manufacturer). In contrast, the second power semiconductor switch 332 is actuated by means of a gate-emitter voltage that is increased in relation to the nominal gate-emitter voltage. The gate-emitter voltages used are able to be determined once upon start-up or dynamically, repeatedly and during operation.

1. An apparatus for limiting a fault current in a DC voltage connection, the apparatus comprising:
a series connection of current-limiting modules, each of said current-limiting modules having a plurality of power semiconductor switches and a surge arrester connected in parallel with said power semiconductors switches; and
a controller for controlling said power semiconductor switches, said controller configured to actuate said power semiconductor switches by means of different gate-emitter voltages.

2. The apparatus according to claim 1, wherein said controller is configured to actuate at least a first power semiconductor switch of a current-limiting module by means of a first gate-emitter voltage that corresponds to a nominal gate-emitter voltage, and to actuate at least a second power semiconductor switch of said current-limiting module by means of a second gate-emitter voltage, a magnitude of said second gate-emitter voltage is higher than the nominal gate-emitter voltage.

3. The apparatus according to claim 1, wherein at least one of said current-limiting modules has at least two said power semiconductor switches which are disposed in a series connection.

4. The apparatus according to claim 1, wherein at least one of said current-limiting modules contains at least two said power semiconductor switches, which are disposed in antiseries with one another.

5. The apparatus according to claim 1, wherein at least one of said current-limiting modules contains at least two said power semiconductor switches, which are disposed in a parallel connection with one another.

6. The apparatus according to claim 1, wherein at least one of said current-limiting modules contains at least four of said power semiconductor switches, which are disposed in a parallel connection of in each case two said power semiconductor switches disposed in antiseries with one another.

7. The apparatus according to claim 1, wherein at least one of said current-limiting modules contains a bypass switch for bypassing said at least one current-limiting module in an event of a fault.

8. The apparatus according to claim 1, wherein at least one of said current-limiting modules has a parallel resistor that is connected in parallel with said surge arrester.

9. The apparatus according to claim 1, further comprising a power supply for supplying energy to said current-limiting modules, said power supply being galvanically isolated from said current-limiting modules.

10. The apparatus according to claim 1, further comprising an active cooling system, said power semiconductor switches are able to be cooled by means of said active cooling system.

11. A DC voltage network, comprising:
DC voltage connections;
a plurality of power converters that are connected to one another by means of said DC voltage connections; and
at least one apparatus according to claim 1, by means of said at least one apparatus it is possible to limit a fault current in one of said DC voltage connections.

12. A method for limiting a fault current in a DC voltage connection by means of an apparatus containing a series connection of current-limiting modules, wherein each of the current-limiting modules has a plurality of power semiconductor switches and a surge arrester connected in parallel with said power semiconductors, the apparatus further having a controller for controlling the power semiconductor switches, the method includes the step of:
actuating the power semiconductor switches by means of different gate-emitter voltages.
